(19) United States
(12) Patent Application Publication
(10) Pub. No.: US 2022/0181183 A1
(43) Pub. Date: Jun. 9, 2022

(54) GAS PLUG, ELECTROSTATIC ATTRACTION MEMBER, AND PLASMA TREATMENT DEVICE

(71) Applicant: KYOCERA Corporation, Kyoto-shi, Kyoto (JP)

(72) Inventors: Yuuji KAWASE, Otsu-shi, Shiga (JP); Yukio NOGUCHI, Koka-shi, Shiga (JP)

(21) Appl. No.: 17/599,206

(22) PCT Filed: Mar. 26, 2020
(86) PCT No.: PCT/JP2020/013782

§ 371 Date: Sep. 28, 2021

(30) Foreign Application Priority Data
Mar. 29, 2019 (JP) 2019-065773

(51) Int. Cl. H01L 21/683; H01J 37/32; C04B 35/565; C04B 38/00; C04B 41/49; C04B 41/84

(52) U.S. Cl. CPC H01L 21/6833; H01J 37/3244; C04B 41/84; C04B 38/0064; C04B 41/4933; C04B 35/565

(57) ABSTRACT

A gas plug of the present disclosure is composed of a columnar porous composite in which a plurality of silicon compound phases containing silicon carbide as a main component are connected to each other via a silicon phase having silicon as a main component. The porous composite is housed inside a tubular body made from a dense ceramic.

### TECHNICAL FIELD

The present disclosure relates to a gas plug, an electrostatic attraction member, and a plasma etching device.

### BACKGROUND ART

Typically, a substrate support assembly such as an electrostatic chuck that attracts and supports a semiconductor substrate is used inside a semiconductor manufacturing device such as a plasma treatment device.

For example, Patent Document 1 describes, as illustrated in FIG. 8, a substrate support assembly 422 including a mounting plate 465, an insulation plate 460, an equipment plate 458, a thermally conductive base 455, and an electrostatic puck 430, and indicates that the electrostatic puck 430 is bonded to the thermally conductive base 455 by an adhesive 450 (e.g., a silicone adhesive). An O-ring 445 is disposed around the adhesive 450 to protect the adhesive 450. The substrate support assembly 422 has a through hole penetrating through the electrostatic puck 430, the adhesive 450, the thermally conductive base 455, the equipment plate 458, the insulation plate 460, and the mounting plate 465, and helium gas is supplied from the back surface side of the mounting plate 465 through this through hole such that a semiconductor substrate (not illustrated) can be cooled. Gas plugs 405, 435 are mounted in the through hole to inhibit the permeation of corrosive etching gas into the substrate support assembly 422. Patent Document 1 also indicates that the gas plugs 405, 435 are made from a ceramic, a metal-ceramic composite (e.g., AlO/SiO, AlO/MgO/SiO, SiC, SiN, and AlN/SiO), a metal (e.g., aluminum, stainless steel), a polymer, a polymer ceramic composite material, Mylar, or polyester.
Patent Document 1: JP 2018-162205 A

### SUMMARY

The gas plug of the present disclosure is composed of a columnar porous composite, the porous composite including a plurality of silicon compound phases which are connected to each other via a silicon phase including silicon as a main component.

The electrostatic attraction member of the present disclosure includes the gas plug mounted inside a ventilation hole that extends in a thickness direction.

The plasma treatment device of the present disclosure is provided with a treatment chamber and the electrostatic attraction member inside the treatment chamber.

### BRIEF DESCRIPTION OF DRAWINGS

FIG. 1 is a schematic view illustrating an overview of a plasma treatment device using an electrostatic attraction member provided with a gas plug of the present disclosure.

FIG. 2 is an enlarged cross-sectional view illustrating an example of an electrostatic attraction member provided with the gas plug of the present disclosure.

FIG. 3(a) is a perspective view illustrating an example of the gas plug of FIGS. 1 and 2, and FIG. 3(b) is an enlarged view of a main portion in a cross-section taken along line A-A′ in FIG. 3(a).

FIG. 4(a) is a perspective view illustrating another example of the gas plug of FIGS. 1 and 2, and FIG. 4(b) is an enlarged view of the main portion in a cross-section taken along line B-B′ in FIG. 4(a).

FIG. 5 is a structural image of a porous composite forming a gas plug of the present disclosure.

FIG. 6 is an example of a cumulative distribution curve showing the relationship between the pore diameter D of the pores present in a sample cut from the porous composite and the cumulative volume of the pores.

FIGS. 7(a) and (b) are perspective views illustrating other examples of the gas plug of FIGS. 1 and 2.

FIG. 8 is a cross-sectional view illustrating an example of an electrostatic attraction member provided with a known gas plug.

### DESCRIPTION OF EMBODIMENTS

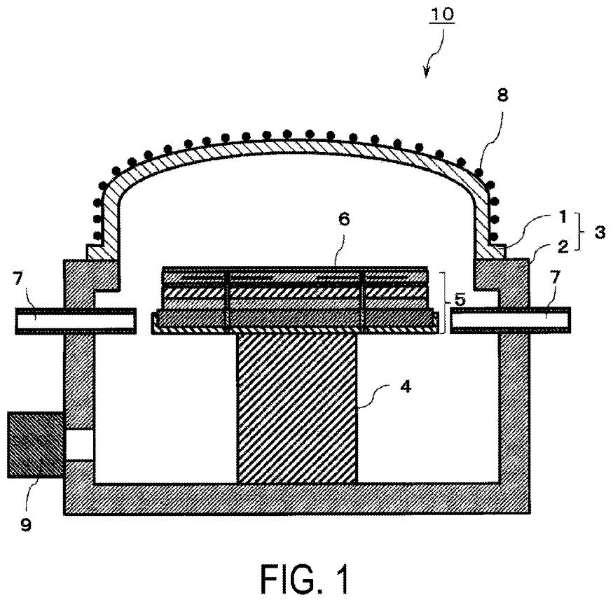

A gas plug, an electrostatic attraction member, and a plasma treatment device according to the present disclosure will be described in detail below with reference to the drawings. FIG. 1 is a schematic view illustrating an overview of a plasma treatment device in which is used an electrostatic attraction member provided with a gas plug of the present disclosure.

The plasma treatment device 10 illustrated in FIG. 1 is provided with a treatment chamber 3 including a dome-shaped upper container 1 and a lower container 2 disposed below the upper container 1. A support table 4 is disposed inside the treatment chamber 3 at the lower container 2 side, and an electrostatic chuck 5, which is an example of an electrostatic attraction member, is provided on the support table 4. A direct current power source (not illustrated) is connected to an attraction electrode of the electrostatic chuck 5, and a semiconductor substrate 6 is attracted and supported on the placement surface of the electrostatic chuck 5 through the supply of electricity.

In addition, a vacuum pump 9 is connected to the lower container 2, and a vacuum state can be formed inside the treatment chamber 3. In addition, a gas nozzle 7 that supplies an etching gas is provided in a peripheral wall of the lower container 2. A peripheral wall of the upper container 1 is provided with an induction coil 8 that is electrically connected to an RF power supply.

When the semiconductor substrate 6 is to be etched using the plasma treatment device 10, first, the treatment chamber 3 is exhausted to a predetermined vacuum degree by the vacuum pump 9. Next, after the semiconductor substrate 6 is attracted to the placement surface of the electrostatic chuck 5, etching gas such as CF₄ gas, for example, is supplied through the gas nozzle 7, and electricity is supplied to the induction coil 8 from the RF power supply. Through this supply of electricity, a plasma of the etching gas is formed in the internal space above the semiconductor substrate 6, and the semiconductor substrate 6 can be etched in a predetermined pattern.

Here, examples of the etching gas include halogen-based gases, such as a fluorine-based gas that is a fluorine compound, such as CF₄, SF₆, CHF₃, ClF₃, NF₃, C₄F₈, or HF, a chlorine-based gas that is a chlorine compound, such as Cl₂, HCl, BCl₃, or CCl₄, or a bromine-based gas that is a bromine compound, such as Br₂, HBr, or BBr₃.

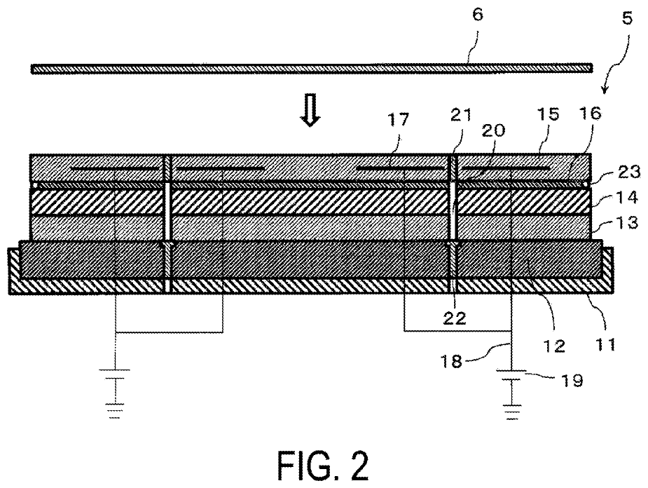

FIG. 2 is an enlarged cross-sectional view illustrating an example of the electrostatic chuck illustrated in FIG. 1. The electrostatic chuck 5 illustrated in FIG. 2 includes a mounting plate 11, an insulating plate 12, an equipment plate 13, a heat transfer member 14, and an insulating base 15. The insulating base 15 is bonded to the heat transfer member 14 through a bonding layer 16.

The insulating base 15 is a member for mounting an object to be treated, such as a semiconductor substrate 6. This insulating base 15 is made from a ceramic containing aluminum oxide, yttrium oxide, or aluminum nitride as a main component. An attraction electrode 17 made from a metal such as platinum, molybdenum, or tungsten is provided inside the insulating base 15. A lead wire 18 is connected to the attraction electrode 17, and the attraction electrode 17 is connected to a direct current power supply 19 through the lead wire 18.

The electrostatic chuck 5 has a ventilation hole 20 penetrating through the insulating base 15, the bonding layer 16, the heat transfer member 14, the equipment plate 13, the insulating plate 12, and the mounting plate 11 in the thickness direction, and is configured to cool the semiconductor substrate 6 by flowing helium gas into the ventilation hole 20 from the back surface side of the mounting plate 11.

The heat transfer member 14 is a member that allows heat generated inside the insulating base 15 to escape downward, and is made from aluminum (Al), copper (Cu), nickel (Ni), or alloys thereof.

The bonding layer 16 is a member for bonding the insulating base 15 and the heat transfer member 14, and is formed from, for example, a resin such as an epoxy resin, a fluorine resin, or a silicone resin. The thickness of the bonding layer 16 is, for example, from 0.1 mm to 2.0 mm.

An annular member 23 is made from a resin such as an epoxy, fluorine, or silicone resin, and is disposed on an end surface side of the bonding layer 16 to suppress degradation of the bonding layer 16 due to the etching gas.

The gas plugs 21 and 22 of the present disclosure are mounted inside the ventilation hole 20 (at both end portions in the example illustrated in FIGS. 1 and 2), and can capture particles generated by the supply of etching gas.

In addition, the gas plugs 21, 22 can suppress the formation of secondary plasma in the ventilation hole 20.

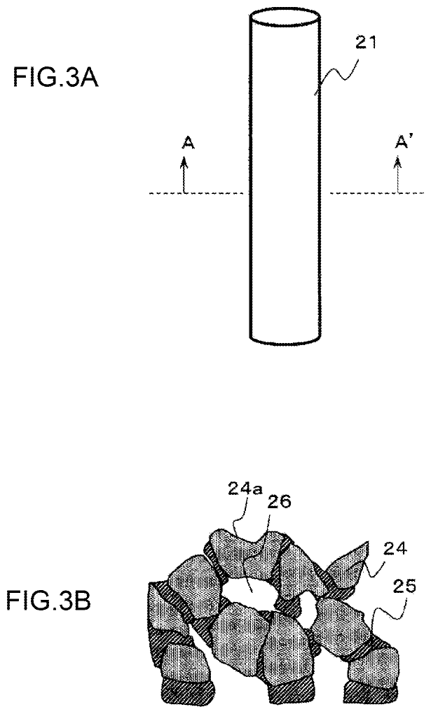

FIG. 3(a) is a perspective view illustrating an example of the gas plug of FIGS. 1 and 2, and FIG. 3(b) is an enlarged view of a main portion in a cross-section taken along line A-A′ in FIG. 3(a).

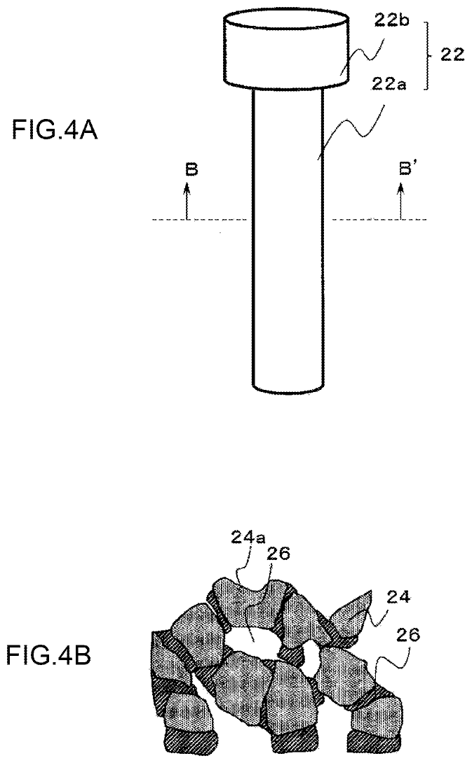

Also, FIG. 4(a) is a perspective view illustrating another example of the gas plug of FIGS. 1 and 2, and FIG. 4(b) is an enlarged view of a main portion in a cross-section taken along line B-B′ in FIG. 4(a).

The gas plug 21 illustrated in FIG. 3(a) is a straight cylindrical body. The gas plug 22 illustrated in FIG. 4(a) includes a cylindrical shaft portion 22a and a tip portion 22b having a diameter that is larger than the diameter of the shaft portion at a distal end side of the shaft portion 22a. As illustrated in FIGS. 3(b) and 4(b), the gas plugs 21 and 22 are formed from a porous composite including a plurality of silicon compound phases 24 connected via a silicon phase 25 having silicon as a main component. Due to the silicon compound phases 24 having high mechanical strength connected via the silicon phases 25 having both high thermal conductivity and high electric conductivity, the gas plugs 21 and 22 have high thermal conductivity and mechanical strength, and arc discharging of the plasma that is flowed can be suppressed.

Note that the main component of the silicon compound phase 24 is, for example, silicon nitride (Si₃N₄), silicon carbide (SiC), silicon carbonitride (SiCₓN_{y}, where x and y are numerical values satisfying 4x+3y=4 in ranges of 0<x<1 and 0<y<4/3, respectively), silicon oxide (SiO₂), or SiAlON (Si_{6-z}Al_{z}O_{z}N_{8-z}, where z is a numerical value satisfying 0.1≤z≤1), and these compositions may be stoichiometric or nonstoichiometric.

The content of the components constituting the silicon compound phase 24 may be determined using an energy dispersive X-ray spectrometer attached to a scanning electron microscope. Furthermore, the silicon compound can be identified using an X-ray diffractometer.

Here, the porous composite has pores 26, and the porosity measured using mercury porosimetry described below is 10 vol. % or greater.

In addition, the porous composite is formed with a three-dimensional mesh structure in which a plurality of silicon compound phases 24 are three-dimensionally arranged, and adjacent silicon compound phases 24 are bonded by a silicon phase 25 having silicon as a main component, and the silicon compound phase 24 may be surrounded by the silicon phase 25. In particular, the silicon compound phase 24 preferably contains silicon carbide as the main component.

When silicon carbide is the main component, the wettability of the silicon phase 25 is good, and therefore the bonding strength between the silicon compound phases 24 can be increased. In addition, since both silicon and silicon carbide have high thermal conductivity, the semiconductor substrate 6 can be efficiently cooled.

Moreover, the cross-sectional shape of the silicon compound phase 24 may be a polygonal shape. With such a configuration, particles generated by the supply of an etching gas can be more easily captured by the silicon compound phase 24 than when the cross-sectional shape is spherical.

Additionally, at least one surface of the silicon compound phase 24 may have a recessed portion 24a. With such a configuration, particles generated by the supply of etching gas can be more easily captured by the recessed portion 24a.

The content of silicon in the silicon phase 25 is 90 mass % or greater for each silicon phase 25, and the silicon phase 25 may include Al, Fe, Ca, and the like as unavoidable impurities. In particular, the content of silicon in the silicon phase 25 is preferably not less than 99 mass %, and the total content of unavoidable impurities is preferably not greater than 1 mass %.

In particular, the content of iron in the silicon phase 25 is preferably not greater than 0.4 mass %. When the iron content is within this range, the risk that iron forms particles and the particles float in the plasma treatment device is reduced.

The content of the components constituting the silicon phase 25 may be determined using an energy dispersive X-ray spectrometer attached to a scanning electron microscope.

Also, with the porous composite, the average pore diameter affects pressure loss, and when the average pore diameter is small, there is a concern that the pressure loss may increase. On the other hand, when the average pore diameter is large, the surface of the semiconductor substrate 6 is likely to have large recess-shaped depressions along the pores when the semiconductor substrate 6 has been attracted, and after etching, the flatness of the surface of the semiconductor substrate 6 may increase.

From this perspective, the average pore diameter of the porous composite is preferably from 30 μm to 100 μm.

When the average pore diameter of the porous composite is within this range, there is no increase in pressure loss, and the flatness of the surface of the semiconductor substrate 6 is not increased.

The average pore diameter of the porous composite can be determined by mercury porosimetry in accordance with JIS R 1655-2003.

Specifically, first, a cubic sample having a length of side from 6 to 7 mm is cut out from the porous composite. Next, mercury is pressed into the pores present in the sample using a mercury intrusion porosimeter, and the pressure applied to the mercury and the volume of mercury permeated into the pores are measured. This volume is equivalent to the volume of the pores, and the following equation (2) (Washburn equation) holds true for the pressure applied to the mercury and the pore diameter.

D=−4γ cos θ/p (2)

Where, D: Pore diameter (m)

p: Pressure applied to the mercury

γ: Surface tension of the mercury (0.48 N/m)

θ: Contact angle between the mercury and the pore wall surface)(140°

Each pore diameter D is determined from equation (2) for each pressure p, and the volume distribution and cumulative volume of the pores can be derived therefrom for each pore diameter D.

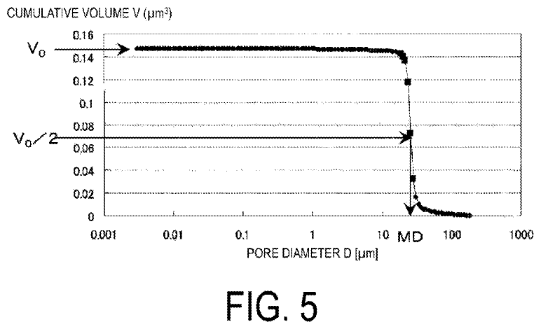

FIG. 5 is an example of a cumulative distribution curve showing the relationship between the pore diameter D of the pores present in a sample cut from the porous composite and the cumulative volume of the pores. In this cumulative distribution curve, when the total cumulative volume of the pores is denoted by Vo, the pore diameter at which the cumulative volume of the pores is Vo/2 is the average pore diameter (MD).

In addition, in the cumulative distribution curve showing a relationship between the pore diameter and the cumulative volume of the pores, the porous composite preferably has a ratio (p80/p20) of from 1.2 to 1.6, the ratio (p80/p20) being a cumulative 80 vol. % pore diameter (p80) to a cumulative 20 vol. % pore diameter (p20). When the ratio (p80/p20) is within this range, particles of various sizes included in the etching gas can be captured, and an increase in pressure loss can be suppressed, and therefore the risk of detachment from the electrostatic attraction member caused by an increase in pressure loss can be reduced.

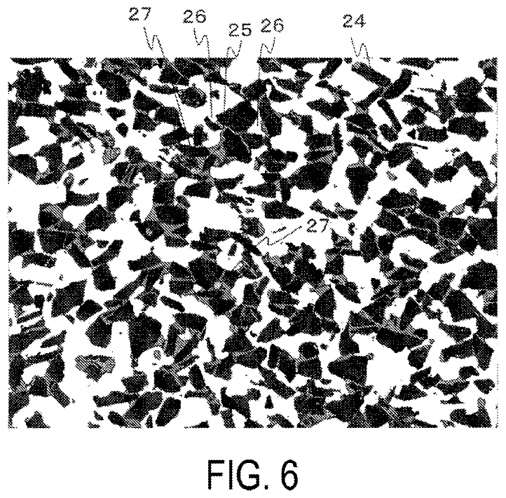

FIG. 6 is a structural image of a porous composite forming the gas plug of the present disclosure. The porous composite illustrated in FIG. 6 has a three-dimensional mesh structure that has pores 26 and in which the silicon compound phases 24 having silicon carbide as a main component are three-dimensionally arranged, and adjacent silicon compound phases 24 are bonded via a silicon phase 25. The surface area of non-connected parts 27, which are gaps and air bubbles in the silicon phases 25, is preferably as small as possible. The reason is explained. The wettability of silicon for silicon carbide is good, and therefore silicon is easily adhered to the silicon compound phase 24, and the adhered silicons are connected to each other to form the silicon phase 25. In this formation process, a non-connected part 27 may occur inside the silicon phase 25, and this non-connected part 27 reduces thermal conductivity. Therefore, it is preferable that the surface area of the non-connected parts 27, which are gaps and air bubbles in the silicon phases 25, is as small as possible.

When the area ratio of the non-connected part 27 in an observation range (2200 μm×1700 μm) in a cross-section of the porous composite is expressed by the following equation (1), the area ratio of the non-connected part 27 is preferably not greater than 3.5%.

(Area ratio of non-connected part 27)={(surface area of non-connected part 27)/(surface area of silicon phase 25+surface area of non-connected part 27)}×100(%) (1)

In order to determine the area ratio of the non-connected part 27, first, a portion of the porous composite is embedded in a polyester-based cold-embedding resin (for example, No. 105 available from Marumoto Struers K.K.) and formed into a cylindrical sample. An end surface of this sample is then polished using diamond abrasive grains (for example, FDCW-0.3 available from Fujimi Incorporated) to form a mirror surface. Subsequently, this mirror surface is photographed at a magnification from 5 to 50 using an industrial microscope (Eclipse LV150, available from Nikon Corporation), and the obtained images are stored in JPEG format.

Next, the image files stored in JPEG format are subjected to image processing using the software Adobe Photoshop Elements (trade name), and are stored in BMP format. Specifically, the chromatic colors in the images are deleted, and the images are converted to black and white duotone (black-and-white conversion) images. In this duotone conversion, a threshold value at which the silicon compound phase 24 and the silicon phase 25 can be identified is set while comparing images captured by the industrial microscope (Eclipse LV150, available from Nikon Corporation).

After the threshold value has been set, the surface area of the silicon phase 25 is read in pixel units using, for example, a free software called “Surface area from images” (creator: Teppei AKAO).

Then, the non-connected parts 27, which are gaps or air bubbles in the silicon phase 25, in the duo-tone converted image are colored with colors other than black and white through image processing, the surface area of the non-connected parts 27 is read in the same manner as described above, and if the surface area of the silicon phase 25 and the surface area of the non-connected parts 27 are substituted into equation (1), the area ratio of the non-connected parts 27 can be determined.

Additionally, the porosity of the porous composite may be from 20 vol. % to 40 vol. %.

When the porosity is within this range, pressure loss does not increase, and thermal conductivity and mechanical strength do not decrease. Porosity of the porous composite can be determined by the Archimedes method.

The thermal conductivity is, for example, 50 W/(m·K) or higher. The thermal conductivity may be determined in accordance with JIS R 1611:2010 (ISO 18755:2005).

The three-point bending strength, which indicates the mechanical strength, is, for example, 20 MPa or greater. The three-point bending strength may be measured in accordance with JIS R 1601:2008 (ISO 14704:2000).

The average diameter of the silicon compound phase 24 may be from 105 μm to 350 μm. The average diameter of the silicon compound phase 24 is measured by an intercept method using an image with a magnification from 20 to 800, obtained using, for example, a scanning electron microscope (hereinafter, a scanning electron microscope is referred to as an SEM), or can be determined by calculating through image analysis the equivalent circle diameters of a quantity of from 10 to 30 silicon compound phases 24 observed in a range from 0.2 to 2.0 mm×from 0.2 to 2.0 mm, for example, in an image obtained at a magnification of from 20 to 800 using an SEM, and calculating the average value of the equivalent circle diameters. When the intercept method is used, specifically, the average diameter is measured from a quantity of silicon compound phases 24 on a straight line of a certain length from several SEM images such that the quantity of silicon compound phases 24 is 10 or greater, and preferably 20 or greater.

A water-repellent resin having electrical conductivity may be adhered around a periphery of the silicon compound phases 24 and silicon phases 25. When the water-repellent resin having electrical conductivity is adhered, the electrostatic adherence of floating particles to the silicon compound phases 24 and the silicon phases 25 can be suppressed. Having electrical conductivity means that the surface resistance is 10¹² S2 or less. Further, the surface resistance of the adhered water-repellent resin is preferably from 10⁶ to 10¹²Ω.

The water-repellent resin is preferably a fluorine resin or a silicone resin. This is because these resins exhibit high water-repellency performance. In particular, the water-repellent resin is preferably a compound containing a fluorinated polysiloxane or a composition containing a silicone oligomer.

A lotus effect is obtained in which after washing with a water-soluble detergent, water droplets adhered to the surface of the water-repellent resin adsorb contamination, and therefore the efficiency of removing contamination adhered inside the porous composite can be increased.

The water-repellent resin may be identified using a Fourier transform infrared spectrometer (FTIR) or a gas chromatograph (GC mass). For example, if the water-repellent resin is a fluorine resin, the power spectrum can be measured by FTIR, and the water-repellent resin can be identified by comparing the standard power spectrum of the fluorine resin and the measured power spectrum. For a case in which GC mass is used, if polytetrafluoroethylene (PTFE), tetrafluoroethylene (TFE), hexafluoroethylene (HFE), or the like is detected as the thermally decomposed gas, the water-repellent resin can be identified as a fluorine resin.

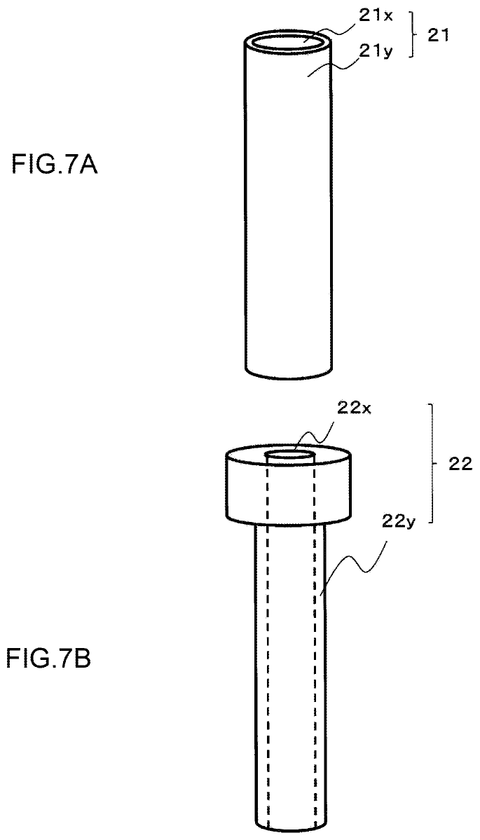

FIGS. 7(a) and (b) are each perspective views illustrating other examples of the gas plug of FIGS. 1 and 2. The gas plugs 21 and 22 illustrated in FIGS. 7(a) and 7(b) each include a porous composite 21x or 22x and a tubular body 21y or 22y made from a dense ceramic. The porous composites 21x, 22x are housed within the tubular bodies 21y, 22y, respectively. With such a configuration, when the gas plugs 21, 22 are mounted in a ventilation hole 20, the porous composites 21x, 22x are covered by the tubular bodies 22y, 22y, which are higher in mechanical strength than the porous composites 21x, 22x, and therefore the risk of damage to the porous composites 21x, 22x can be reduced. The dense ceramic in the present disclosure refers to a ceramic having a porosity of less than 10 vol. %, and may be measured using the Archimedes method.

Furthermore, the dense ceramic is preferably a ceramic having aluminum oxide or silicon carbide as the main component.

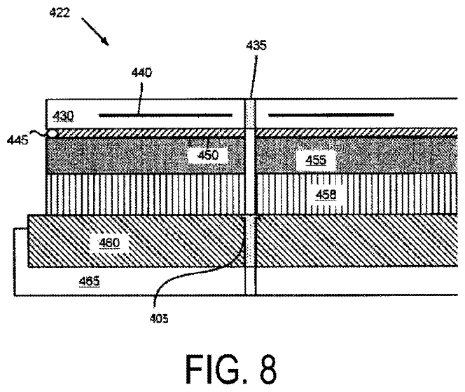

Note that the plasma treatment device 10 illustrated in FIG. 1 is a plasma etching device, but besides a plasma etching device, for example, an electrostatic attraction member provided with a gas plug illustrated in FIGS. 3, 4 and 8 may be used in a device, such as a plasma CVD film forming device, in which plasma generation is performed using a corrosive gas.

Next, an example of a method for manufacturing the gas plug of the present disclosure will be described.

First, from 5 to 30 parts by mass of a silicon powder having an average particle size from 1 to 90 μm is mixed with 100 parts by mass of an α-type silicon carbide powder having an average particle size from 90 to 250 μm, and then, as a molding aid, at least one of a thermosetting resin having a residual carbon ratio of 10% or greater after a subsequent degreasing treatment, such as, for example, a phenol resin, an epoxy resin, a furan resin, a phenoxy resin, a melamine resin, a urea resin, an aniline resin, an unsaturated polyester resin, a urethane resin, or a methacrylic resin, is added and wet mixed using a ball mill, a vibrating mill, a colloid mill, an attritor, a high-speed mixer, or the like. In particular, a resol or novolac type phenol resin is preferable as the molding aid from the perspective of low shrinkage after thermal curing.

Here, in order to obtain a gas plug in which the cross-sectional shape of the silicon compound phase is a polygonal shape, the α-type silicon carbide powder may be GC abrasive grains that are used as an abrasive.

In addition, in order to obtain a gas plug having a recessed portion in at least one surface of the silicon compound phase, GC abrasive grains having a recessed portion in the surface may be used.

In order to obtain a gas plug in which the ratio (p80/p20) of the pore diameters of the porous composite is from 1.2 to 1.6, an α-type silicon carbide powder having an average particle size from 110 to 230 μm may be used.

In order to obtain a gas plug in which the porosity of the porous composite is from 20 vol. % to 40 vol. %, and the average pore diameter is from 30 μm to 100 μm, the addition amount of the molding aid may be from 5 to 20 parts by mass per 100 parts by mass of the α-silicon carbide powder.

In addition, the silicon powder is formed into a silicon phase by a subsequent thermal treatment, and a silicon compound phase containing silicon carbide as the main component is connected thereto.

The purity of the silicon powder is preferably high, and a silicon powder having a purity of 95 mass % or higher is preferable, and a silicon powder having a purity of 99 mass % or higher is particularly preferable. Note that the shape of the silicon powder is not particularly limited and may be not only spherical or a shape close to spherical, but also an irregular shape.

The average particle size of the α-type silicon carbide powder and silicon powder can be measured by liquid phase precipitation, light dropping, laser scattering diffraction, or the like.

Next, granules are obtained by granulating a mixture of the α-type silicon carbide powder, the silicon powder, and the molding aid using various granulators such as a rolling granulator, a spray drier, a compression granulator, and an extrusion granulator.

The obtained granules are molded by a molding method such as dry compression molding or cold isotropic hydrostatic press molding to form a powder compact.

Next, a degreasing treatment is implemented at a temperature from 400 to 600° C. in a non-oxidizing atmosphere such as argon, helium, neon, nitrogen, or a vacuum. Subsequently, a porous composite in which a plurality of silicon compound phases containing silicon carbide as the main component are connected to each other via a silicon phase can be obtained by thermally treating at a temperature from 1400 to 1450° C. in a non-oxidizing atmosphere. Here, if a porous composite having a porosity from 20% to 40% and an average pore diameter from 30 μm to 100 μm is to be obtained, the thermal treatment is preferably implemented at a temperature from 1420 to 1440° C.

In order to reduce the temperature of the thermal treatment, the purity of the silicon may be set from 99.5 to 99.8 mass %.

The porous composite obtained by this manufacturing method can be subjected to machining such as grinding and polishing both end surfaces and the outer circumferential surface, and thereby the gas plug illustrated in FIGS. 1 and 2 can be obtained.

Furthermore, in order to obtain the gas plugs illustrated in FIG. 7, a paste containing each of the components is applied onto the porous composite, with the content of each of the components being adjusted such that after bonding the paste to the outer circumferential surface of the porous composite obtained by the manufacturing method described above, the content of each component is, for example, SiO₂: 60 mass %, Al₂O₃: 15 mass %; B₂O₃: 14 mass %, CaO: 4 mass %, MgO: 3 mass %, BaO: 3 mass %, and SrO: 1 mass %. The porous composite coated with the paste is then inserted into the tubular body made of a dense ceramic, and then thermally treated at a temperature from 900° C. to 1100° C., and thereby the gas plugs illustrated in FIG. 7 can be obtained.

When a fluorine resin having electrical conductivity is to be adhered around the periphery of the silicon compound phases and the silicon phases, the gas plug is impregnated with a fluorine resin solution (a solution in which a fluorine resin having electrical conductivity is dissolved in a fluorine-based solvent), and then the gas plug is removed from this solution. The gas plug is then dried at ambient temperature, and then further heated for 1 hour to 2 hours at a temperature from 70° C. to 80° C., and thereby the fluorine resin having electrical conductivity can be adhered. When a silicone resin is to be adhered, the gas plug is impregnated with a silicone resin solution, after which the gas plug is removed from the solution. The gas plug is then dried at ambient temperature, and the silicone resin having electrical conductivity can be adhered.

Embodiments of the present disclosure were described above, but the present disclosure is not limited to the embodiments described above, and various modifications and enhancements can be made.

### REFERENCE SIGNS LIST

1: Upper container
2: Lower container
3: Treatment chamber
4: Support table
5: Electrostatic chuck
6: Semiconductor substrate
7: Gas nozzle
8: Induction coil
9: Vacuum pump
10: Plasma treatment device
11: Mounting plate
12: Insulating plate
13: Equipment plate
14: Heat transfer member
15: Insulating base
16: Bonding layer
17: Attraction electrode
18: Lead wire
19: DC power supply
20: Ventilation hole
21, 22: Gas plug
23: Annular member
24: Silicon compound phase
25: Silicon phase
26: Pore
27: Non-connected part

1. A gas plug comprising a porous composite having a columnar shape, the porous composite comprising a plurality of silicon compound phases which are connected to each other via a silicon phase comprising silicon as a main component.

2. The gas plug according to claim 1, wherein the silicon compound phase comprises silicon carbide as a main component.

3. The gas plug according to claim 1, wherein a cross-sectional shape of the silicon compound phase is a polygonal shape.

4. The gas plug according to claim 1, wherein at least one surface of the silicon compound phases comprises a recessed portion.

5. The gas plug according to claim 1, wherein a content of iron in the silicon phase is not greater than 0.4 mass %.

6. The gas plug according to claim 1, wherein in a cumulative distribution curve showing a relationship between a pore diameter and a cumulative volume of pores, the porous composite has a ratio (p80/p20) of from 1.2 to 1.6, the ratio (p80/p20) being a ratio of a cumulative 80 vol. % pore diameter (p80) to a cumulative 20 vol. % pore diameter (p20).

7. The gas plug according to claim 1, wherein a water-repellent resin having electrical conductivity is adhered around a periphery of the silicon compound phase and the silicon phase.

8. The gas plug according to claim 7, wherein the water-repellent resin is a compound comprising a fluorinated polysiloxane or a composition comprising a silicone oligomer.

9. The gas plug according to claim 1, comprising the porous composite and a tubular body made from a dense ceramic,
wherein the porous composite is housed inside the tubular body.

10. An electrostatic attraction member comprising the gas plug described in claim 1 mounted inside a ventilation hole extending in a thickness direction.

11. A plasma treatment device comprising a treatment chamber and the electrostatic attraction member described in claim 10 inside the treatment chamber.
